(19) United States
(12) Patent Application Publication
(10) Pub. No.: US 2025/0301924 A1
(43) Pub. Date: Sep. 25, 2025

(54) SEMICONDUCTOR DEVICE AND METHOD FOR MANUFACTURING THE SAME

(71) Applicant: United Microelectronics Corp., Hsinchu (TW)

(72) Inventors: Yu-Ting TSENG, Tainan City (TW); Yu-Hsiang LIN, New Taipei City (TW); Zen-Jay TSAI, Tainan City (TW)

(21) Appl. No.: 18/670,765

(22) Filed: May 22, 2024

(30) Foreign Application Priority Data
Mar. 20, 2024 (TW) 113110312

(51) Int. Cl. H10N 70/00; H10B 63/00

(52) U.S. Cl. CPC H10N 70/841; H10B 63/00; H10N 70/021; H10N 70/063

(57) ABSTRACT

A semiconductor device is provided. The semiconductor device includes a RRAM device. The RRAM device includes a bottom electrode, a resistance variable layer, and a top electrode. The bottom electrode has a V-shaped portion. The V-shaped portion of the bottom electrode has a flat surface at a top side and has a flat surface at a bottom side. The resistance variable layer is disposed on the bottom electrode. The resistance variable layer has a V-shaped portion. The V-shaped portion of the resistance variable layer forms a sharp angle at a top side and has a flat surface at a bottom side. The top electrode is disposed on the resistance variable layer. The top electrode has a flat body and a protruding portion. The protruding portion is located on a bottom side of the flat body and has a sharp end directing towards the resistance variable layer.

This application claims the benefit of Taiwan application Serial No. 113110312, filed Mar. 20, 2024, the subject matter of which is incorporated herein by reference.

### BACKGROUND OF THE INVENTION

### Field of the Invention

The invention relates in general to a semiconductor device and a method for manufacturing the same, and more particularly to a semiconductor device having a resistive random access memory (RRAM) device and a method for manufacturing the same.

### Description of the Related Art

A resistive random access memory, as a non-volatile memory, has a simple structure, tiny size, scalability, ultra-high-speed operation, low-power operation, and the compatibility to the complementary metal oxide semiconductor (CMOS), low cost and other advantages. A simple structural example of a resistive random access memory includes a resistance variable layer sandwiched between two electrodes. A suitable electric field can induce a soft breakdown of the resistance variable layer, thereby establishing a conductive filament path to connect the two electrodes. The filament path can be formed by different mechanisms, such as oxygen vacancy or migration of metal defects. The resistance variable layer has a resistance that can vary between two or more stable resistance ranges, which correspond to different logic states of the memory cell.

### SUMMARY OF THE INVENTION

The invention is directed to an improvement of a resistive random access memory, and more particularly to the formation of the filament to improve the relevant electrical properties.

According to some embodiments, a semiconductor device is provided. The semiconductor device includes a RRAM device. The RRAM device includes a bottom electrode, a resistance variable layer, and a top electrode. The bottom electrode has a V-shaped portion. The V-shaped portion of the bottom electrode has a flat surface at a top side and has a flat surface at a bottom side. The resistance variable layer is disposed on the bottom electrode. The resistance variable layer has a V-shaped portion. The V-shaped portion of the resistance variable layer forms a sharp angle at a top side and has a flat surface at a bottom side. The top electrode is disposed on the resistance variable layer. The top electrode has a flat body and a protruding portion. The protruding portion is located on a bottom side of the flat body and has a sharp end directing towards the resistance variable layer.

According to some embodiments, a method for manufacturing a semiconductor device is provided. The method for manufacturing the semiconductor device includes forming a RRAM device. The method for forming the RRAM device includes the following steps. Firstly, a bottom electrode is formed on a lower semiconductor structure and into a recess of the lower semiconductor structure. The bottom electrode has a V-shaped portion. The V-shaped portion of the bottom electrode has a flat surface at a top side and has a flat surface at a bottom side. Then, a resistance variable layer is formed on the bottom electrode. The resistance variable layer has a V-shaped portion. The V-shaped portion of the resistance variable layer forms a sharp angle at a top side and has a flat surface at a bottom side. Thereafter, a top electrode is formed on the resistance variable layer. The top electrode has a flat body and a protruding portion. The protruding portion is located on a bottom side of the flat body and has a sharp end directing towards the resistance variable layer.

The sharp end of the top electrode causes a “tip effect”, and the filament will be formed more easily from near the sharp end of the protruding portion, accordingly. Therefore, lower voltages can be used to form filaments. Thus, the formation efficiency of filaments can be improved. Also, the lower stress can improve random access performance.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of an exemplary semiconductor device according to the present invention.

FIG. 2 is a schematic diagram of the operation of an exemplary semiconductor device according to the present invention.

FIG. 3 is a flowchart of a method for manufacturing an exemplary semiconductor device according to the present invention.

FIGS. 4A-4F are schematic diagrams of various stages of a method for manufacturing an exemplary semiconductor device according to the present invention.

### DETAILED DESCRIPTION OF THE INVENTION

Various embodiments will be described in more detail below with reference to the accompanying drawings. The contents of description and diagrams are provided for illustration only and are not intended to be limiting. For clarity, some elements and/or symbols may be omitted in some drawings. In addition, elements in the drawings may not be drawn to actual scale. It is contemplated that elements and features in one embodiment can be advantageously incorporated into another embodiment without further description.

A semiconductor device is provided in the present invention. The semiconductor device includes a resistive random access memory (RRAM) device. The RRAM device includes a bottom electrode, a resistance variable layer, and a top electrode. The bottom electrode has a V-shaped portion. The V-shaped portion of the bottom electrode has a flat surface at a top side and has a flat surface at a bottom side. The resistance variable layer is disposed on the bottom electrode. The resistance variable layer has a V-shaped portion. The V-shaped portion of the resistance variable layer forms a sharp angle at a top side and has a flat surface at a bottom side. The top electrode is disposed on the resistance variable layer. The top electrode has a flat body and a protruding portion. The protruding portion is located on a bottom side of the flat body and has a sharp end directing towards the resistance variable layer.

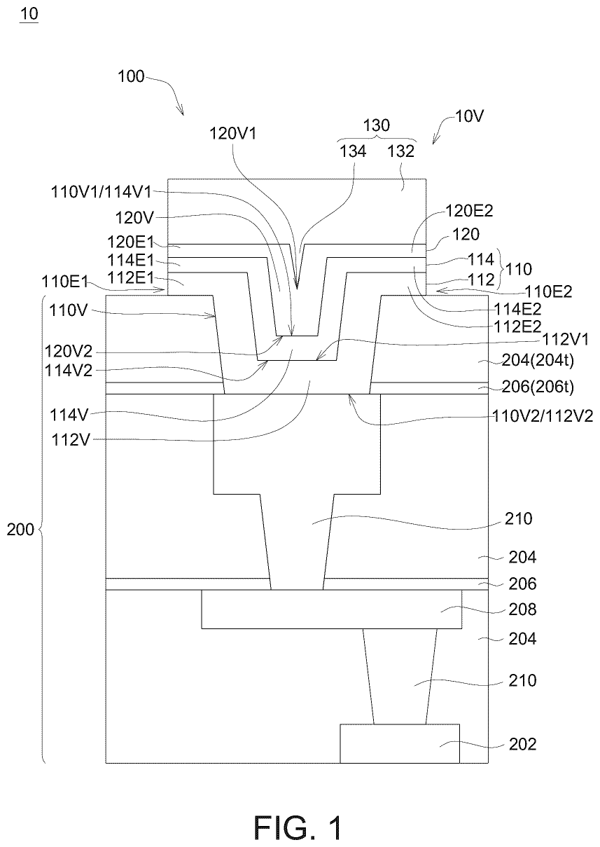

Referring to FIG. 1, an exemplary semiconductor device 10 according to the present invention is shown. The semiconductor device 10 includes a resistive random access memory (RRAM) device 100. The RRAM device 100 includes a bottom electrode 110, a resistance variable layer 120, and a top electrode 130.

The bottom electrode 110 has a V-shaped portion 110V. The V-shaped portion 110V of the bottom electrode 110 has a flat surface 110V1 at an upper side and a flat surface 110V2 at a lower side. The bottom electrode 110 may further have two flat ends 110E1 and 110E2, and the V-shaped portion 110V of the bottom electrode 110 may be disposed between the two flat ends 110E1 and 110E2 and connected to the two flat ends 110E1 and 110E2. According to some embodiments, the bottom electrode 110 may include a first bottom electrode 112 and a second bottom electrode 114. The first bottom electrode 112 has a V-shaped portion 112V. The V-shaped portion 112V of the first bottom electrode 112 has a flat surface 112V1 at an upper side and a flat surface 112V2 at a lower side. The first bottom electrode 112 may further have two flat ends 112E1 and 112E2, and the V-shaped portion 112V may be disposed between the two flat ends 112E1 and 112E2 and connect the two flat ends 112E1 and 112E2. The second bottom electrode 114 is provided on the first bottom electrode 112. The second bottom electrode 114 has a V-shaped portion 114V. The V-shaped portion 114V of the second bottom electrode 114 has a flat surface 114V1 at an upper side and a flat surface 114V2 at a lower side. The second bottom electrode 114 may further have two flat ends 114E1 and 114E2, and the V-shaped portion 114V may be disposed between the two flat ends 114E1 and 114E2 and connect the two flat ends 114E1 and 114E2. In this case, the first bottom electrode 112 and the second bottom electrode 114 constitute the bottom electrode 110, the V-shaped portion 112V and the V-shaped portion 114V constitute the V-shaped portion 110V, the flat surface 112V2 forms a flat surface 110V2, and the flat surface 114V1 forms a flat surface 110V1, the flat end 112E1 and the flat end 114E1 constitute the flat end 110E1, and the flat end 112E2 and the flat end 114E2 constitute the flat end 110E2. Various conductive materials may be used to form bottom electrode 110. For example, the first bottom electrode 112 may be formed of titanium nitride (TiN) or tantalum nitride (TaN), especially titanium nitride (TiN), and the second bottom electrode 114 may be formed of iridium (Ir). However, it is understood that the present invention is not limited thereto.

The resistance variable layer 120 is disposed on the bottom electrode 110. The resistance variable layer 120 has a V-shaped portion 120V. The V-shaped portion 120V of the resistance variable layer 120 forms a sharp angle 120V1 at an upper side and has a flat surface 120V2 at a lower side. The resistance variable layer 120 may further have two flat ends 120E1 and 120E2, and the V-shaped portion 120V of the resistance variable layer 120 may be disposed between the two flat ends 120E1 and 120E2 and connected to the two flat ends 120E1 and 120E2. Various resistance variable materials may be used to form the resistance variable layer 120. For example, the resistance variable layer 120 may be formed of tantalum oxide (TaO) or hafnium oxide (HfO₂), especially tantalum oxide (TaO). However, it is understood that the present invention is not limited thereto.

The top electrode 130 is disposed on the resistance variable layer 120. The top electrode 130 has a flat body 132 and a protruding portion 134. The protruding portion 134 is located at a lower side of the flat body 132 and has a sharp end directed toward the resistance variable layer 120. The sharp end of the protruding portion 134 of the top electrode 130 may be disposed in the sharp angle 120V1 formed by the resistance variable layer 120, and the surface of the protruding portion 134 may be completely in contact with the V-shaped portion 120V of the resistance variable layer 120. Here, the top electrode 130 may have only one protruding portion 134. That is to say, the protruding portion 134 is a single protruding portion. Compared with the arrangement of multiple protruding portions, the arrangement of a single protruding portion may be more conducive to the concentration of the electric field. The sharp end may be a sharp edge (i.e. the line formed by the lowermost portion, which is perpendicular to the paper surface of FIG. 1). Alternatively, the sharp end may be a tip (i.e. the point formed by the lowermost portion). The top electrode 130 and the bottom electrode 110 may be formed of different materials. However, it is understood that the present invention is not limited thereto. For example, the top electrode 130 may be formed of tantalum nitride (TaN) or titanium nitride (TiN), particularly tantalum nitride (TaN).

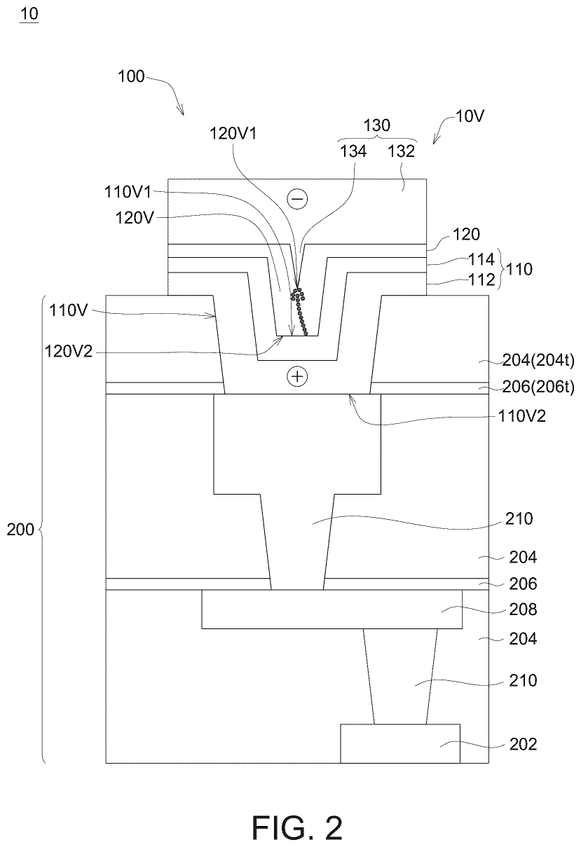

The filament path of oxygen vacancy can be formed in the resistance variable layer 120 of the RRAM device 100 by an electric field, as shown in FIG. 2. For example, the bottom electrode 110 can be used as the positive electrode and the top electrode 130 can be used as the negative electrode. A voltage can be applied to establish or break the filament to set or reset the RRAM device 100.

Since the sharp end of the top electrode creates a “tip effect”, the filament can be formed more easily from near the sharp end of the protruding portion. Therefore, a lower voltage than the commonly used 3.0V to 8.0V can be used to form the filament. Thus, the filament formation efficiency can be improved. Also, lower stress can improve random access performance. Furthermore, since the filament are confined near the sharp end of the protruding portion, more stable endurance is provided.

Please refer to FIG. 1 again, the semiconductor device 10 may further include a lower semiconductor structure 200. For example, the lower semiconductor structure 200 includes at least one of an electronic device 202, dielectric layers (such as a dielectric layer 204 and/or a dielectric layer 206 formed of different materials), conductive layers (such as layers including conductive lines 208), and an interconnecting via 210. In some embodiments, the lower semiconductor structure 200 includes a first top layer 206t (such as the uppermost dielectric layer 206) and a second top layer 204t (such as the uppermost dielectric layer 204). The second top layer 204t is disposed on the first top layer 206t. The second top layer 204t and the first top layer 206t form a recess, and the RRAM device 100 is partially formed in the recess.

According to some embodiments, the RRAM device 100 may be formed as a portion of a via 10V of the semiconductor device 10.

Attention now turns to a method for manufacturing the semiconductor device according to the present invention. The method for manufacturing the semiconductor device includes forming a RRAM device. The method for forming the RRAM device includes the following steps. Firstly, a bottom electrode is formed on a lower semiconductor structure and into a recess of the lower semiconductor structure. The bottom electrode has a V-shaped portion. The V-shaped portion of the bottom electrode has a flat surface at a top side and has a flat surface at a bottom side. Then, a resistance variable layer is formed on the bottom electrode. The resistance variable layer has a V-shaped portion. The V-shaped portion of the resistance variable layer forms a sharp angle at a top side and has a flat surface at a bottom side. Thereafter, a top electrode is formed on the resistance variable layer. The top electrode has a flat body and a protruding portion. The protruding portion is located on a bottom side of the flat body and has a sharp end directing towards the resistance variable layer.

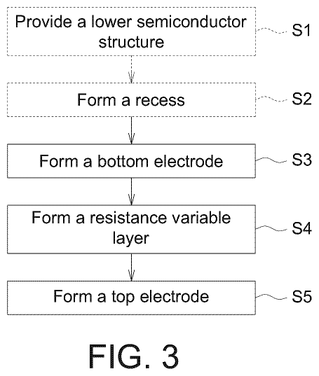

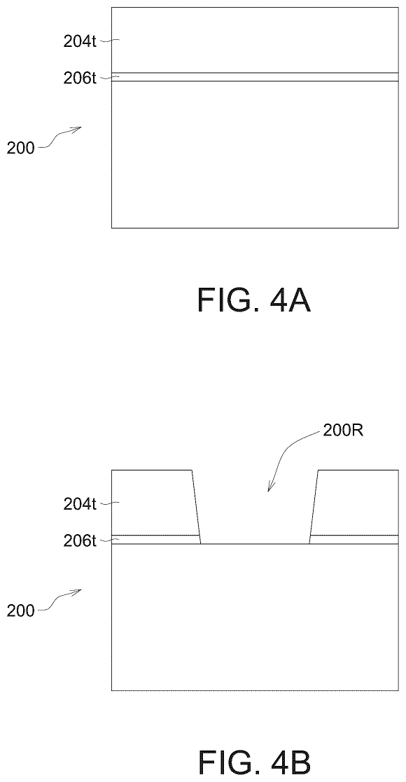

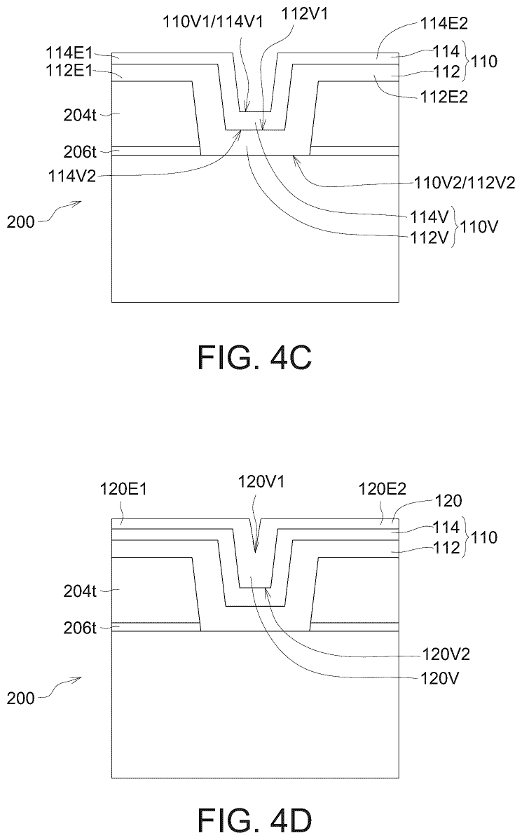

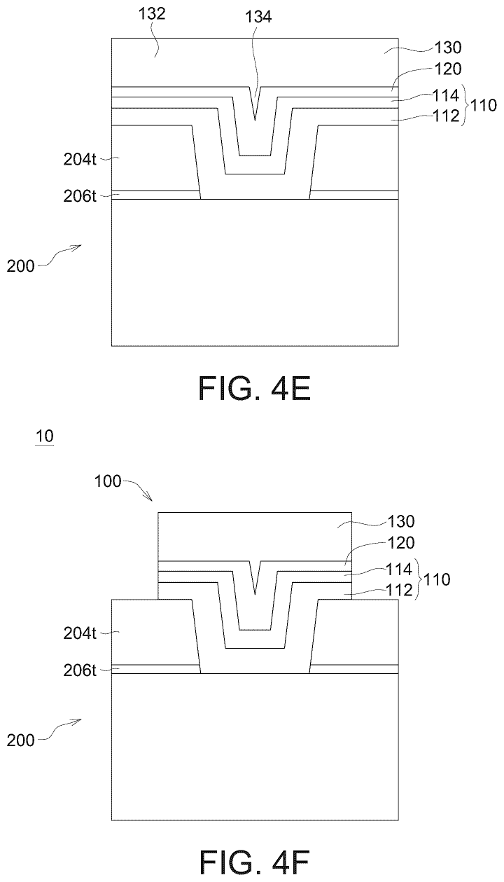

Please refer to FIG. 3 and FIGS. 4A-4F, which illustrate a specific manufacturing method of the semiconductor device 10 as described above. FIG. 3 is a flowchart of a method for manufacturing an exemplary semiconductor device according to the present invention. FIGS. 4A-4F are schematic diagrams of various stages of the method for manufacturing the exemplary semiconductor device according to the present invention.

Firstly, the lower semiconductor structure 200 on which the RRAM device 100 is to be formed may be selectively formed.

For example, in step S1, as shown in FIG. 4A, a lower semiconductor structure 200 may be provided. The lower semiconductor structure 200 includes a first top layer 206t and a second top layer 204t. The second top layer 204t is disposed on the first top layer 206t. For clarity, other details of the lower semiconductor structure 200 are omitted from FIG. 4A and the following figures. However, it can be understood that the lower semiconductor structure 200 may have other features as mentioned above, which will not be described again here.

In step S2, as shown in FIG. 4B, a recess 200R may be formed in the lower semiconductor structure 200, particularly in the second top layer 204t and the first top layer 206t.

Then, a RRAM device 100 may be formed.

In step S3, as shown in FIG. 4C, a bottom electrode 110 is formed on the lower semiconductor structure 200 and into the recess 200R (shown in FIG. 4B) of the lower semiconductor structure 200. The bottom electrode 110 has a V-shaped portion 110V. The V-shaped portion 110V of the bottom electrode 110 has a flat surface 110V1 at an upper side and a flat surface 110V2 at a lower side. More specifically, the step S3 may include conformally depositing a first bottom electrode material onto the lower semiconductor structure 200 and into the recess 200R and conformally depositing a second bottom electrode material onto the first bottom electrode material. The first bottom electrode material may be, but is not limited to, titanium nitride (TiN) or tantalum nitride (TaN), especially titanium nitride (TIN). The first bottom electrode material forms a first bottom electrode 112. The second bottom electrode material may be, but is not limited to, iridium (Ir). The second bottom electrode material forms a second bottom electrode 114. The conformally depositing in step S3 is performed by, for example, but not limited to, a sputtering process. The bottom electrode 110, the first bottom electrode 112, and the second bottom electrode 114 may have other features as described above, which will not be described again here.

In step S4, as shown in FIG. 4D, a resistance variable layer 120 is formed on the bottom electrode 110, wherein the resistance variable layer 120 has a V-shaped portion 120V, and the V-shaped portion 120V of the resistance variable layer 120 forms a sharp angle 120V1 at an upper side and has a flat surface 120V2 at the lower side. The step S4 may include depositing a resistance variable material onto the bottom electrode 110 and wet etching the resistance variable material to form the sharp angle 120V1 corresponding to a V-shaped portion 110V of the bottom electrode 110 (shown in FIG. 4C). At least one of HCl, SC1 (also called APM (ammonia peroxide mixture), which is a mixture of NH₄OH:H₂O₂:H₂O), and SC2 (also called HPM (hydrochloric acid peroxide mixture), which is a mixture of HCl:H₂O₂:H₂O), can be used as an etchant in the wet etching. These etchants, which are commonly used in the wet cleaning process of wafers, can well control the formation of the surface of the sharp angles 120V1. The resistance variable layer 120 may have other features as described above, which will not be described again here.

In step S5, as shown in FIG. 4E, a top electrode 130 is formed on the resistance variable layer 120. The top electrode 130 has a flat body 132 and a protruding portion 134. The protruding portion 134 is located at a lower side of the flat body 132 and has a sharp end directed toward the resistance variable layer 120. The step S5 may include depositing a top electrode material onto the resistance variable layer 120, wherein the top electrode material completely fills the space formed by the V-shaped portion 120V of the resistance variable layer 120 (shown in FIG. 4D). The depositing in step S5 is performed by, for example, but not limited to, a sputtering process. The top electrode 130 may have other features as mentioned above, which will not be described again here.

Then, as shown in FIG. 4F, a patterning process can be selectively performed to define the RRAM device 100.

In summary, the present invention provides a semiconductor device with an improved RRAM device and a method for manufacturing the RRAM device which is simple and compatible to the present process. In the semiconductor device according to the present invention, the special structure of the top electrode of the RRAM device causes a “tip effect”, making it easier for the filament to be formed from near the sharp ends of the protruding portion. Therefore, lower voltages can be used to form the filament. Thus, the filament formation efficiency can be improved. Also, lower stress can improve random access performance.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a RRAM device, the RRAM device comprising:
a bottom electrode having a V-shaped portion, wherein the V-shaped portion of the bottom electrode has a flat surface at a top side and has a flat surface at a bottom side;
a resistance variable layer disposed on the bottom electrode, the resistance variable layer having a V-shaped portion, wherein the V-shaped portion of the resistance variable layer forms a sharp angle at a top side and has a flat surface at a bottom side; and
a top electrode disposed on the resistance variable layer, the top electrode having a flat body and a protruding portion, wherein the protruding portion is located on a bottom side of the flat body and has a sharp end directing towards the resistance variable layer.

2. The semiconductor device according to claim 1, wherein the bottom electrode further have two flat ends, and the V-shaped portion of the bottom electrode is disposed between the two flat ends and connected to the two flat ends.

3. The semiconductor device according to claim 1, wherein the resistance variable layer further have two flat ends, and the V-shaped portion of the resistance variable layer is disposed between the two flat ends and connected to the two flat ends.

4. The semiconductor device according to claim 1, wherein the top electrode has only one of the protruding portion.

5. The semiconductor device according to claim 1, wherein the sharp end of the protruding portion of the top electrode is disposed in the sharp angle formed by the resistance variable layer, and a surface of the protruding portion completely in contact with the V-shaped portion of the resistance variable layer.

6. The semiconductor device according to claim 1, wherein the sharp end is a sharp edge.

7. The semiconductor device according to claim 1, wherein the bottom electrode comprises:
a first bottom electrode having a V-shaped portion, wherein the V-shaped portion of the first bottom electrode has a flat surface at an upper side and a flat surface at a lower side; and
a second bottom electrode disposed on the first bottom electrode, the second bottom electrode having a V-shaped portion, wherein the V-shaped portion of the second bottom electrode has a flat surface at an upper side and a flat surface at a lower side.

8. The semiconductor device according to claim 7, wherein the first bottom electrode is formed of titanium nitride, and the second bottom electrode is formed of iridium.

9. The semiconductor device according to claim 1, wherein the resistance variable layer is formed of tantalum nitride.

10. The semiconductor device according to claim 1, wherein the top electrode and the bottom electrode are formed of different materials.

11. The semiconductor device according to claim 1, wherein the top electrode is formed of tantalum nitride.

12. The semiconductor device according to claim 1, further comprising a lower semiconductor structure, wherein the lower semiconductor structure comprises at least one of an electronic device, a dielectric layer, a conductive layer, and an interconnecting via.

13. The semiconductor device according to claim 12, wherein the lower semiconductor structure comprises a first top layer and a second top layer; the second top layer is disposed on the first top layer; the second top layer and the first top layer form a recess; the RRAM device is partially formed in the recess.

14. The semiconductor device according to claim 1, wherein the RRAM device is formed as a portion of a via of the semiconductor device.

15. A method for manufacturing a semiconductor device, comprising:
forming a RRAM device, comprising:
forming a bottom electrode on a lower semiconductor structure and into a recess of the lower semiconductor structure, wherein the bottom electrode has a V-shaped portion, the V-shaped portion of the bottom electrode has a flat surface at a top side and has a flat surface at a bottom side;
forming a resistance variable layer on the bottom electrode, wherein the resistance variable layer has a V-shaped portion, the V-shaped portion of the resistance variable layer forms a sharp angle at a top side and has a flat surface at a bottom side; and
forming a top electrode on the resistance variable layer, wherein the top electrode has a flat body and a protruding portion, the protruding portion is located on a bottom side of the flat body and has a sharp end directing towards the resistance variable layer.

16. The method according to claim 15, wherein, the step of forming the bottom electrode comprises conformally depositing a first bottom electrode material on the lower semiconductor structure and into the recess, and conformally depositing a second bottom electrode material on the first bottom electrode material.

17. The method according to claim 15, wherein, the step of forming the resistance variable layer comprises depositing a resistance variable material on the bottom electrode, and wet etching the resistance variable material to form the sharp angle corresponding to the V-shaped portion of the bottom electrode.

18. The method according to claim 17, wherein, at least one of HCl, SC1 and SC2 is used as an etchant in the wet etching.

19. The method according to claim 15, wherein, the step of forming the top electrode comprises depositing a top electrode material on the resistance variable layer, wherein the top electrode material completely fills a space formed by the V-shaped portion of the resistance variable layer.
